(19) United States
(12) Patent Application Publication
(10) Pub. No.: US 2023/0370022 A1
(43) Pub. Date: Nov. 16, 2023

(54) ENERGY EFFICIENT AMPLIFICATION FOR AN APPARATUS

(71) Applicant: Nokia Technologies Oy, Espoo (FI)

(72) Inventors: Dirk WIEGNER, Stuttgart (DE); Thales STEDILE RIBEIRO, Ulm (DE)

(21) Appl. No.: 18/044,354

(22) PCT Filed: Jun. 29, 2021
(86) PCT No.: PCT/EP2021/067793

§ 371 Date: Mar. 7, 2023

(30) Foreign Application Priority Data
Sep. 17, 2020 (FI) 20205899

(51) Int. Cl. H03F 1/02; H03F 3/24; H04B 1/44

(52) U.S. Cl. CPC H03F 1/0205; H03F 3/245; H04B 1/44; H03F 2200/451

(57) ABSTRACT

Disclosed is an apparatus comprising means for transmitting a first signal via at least a first switch, a first amplifier, a second switch and a power amplifier, wherein an output of the second switch is connected to a power amplifier path comprising at least the power amplifier, while transmitting the first signal. An input of the first switch and the output of the second switch are switched to switch between transmitting and receiving. A second signal is received via at least the first switch, the first amplifier and the second switch, wherein the output of the second switch is disconnected from the power amplifier path while receiving the second signal.

### FIELD

The following exemplary embodiments relate to wireless communication.

### BACKGROUND

In a device used for wireless communication, it is desirable to improve the energy efficiency of the device.

### SUMMARY

The scope of protection sought for various exemplary embodiments is set out by the independent claims. The exemplary embodiments and features, if any, described in this specification that do not fall under the scope of the independent claims are to be interpreted as examples useful for understanding various exemplary embodiments.

According to an aspect, there is provided an apparatus comprising means for transmitting a first signal via at least a first switch, a first amplifier, a second switch and a power amplifier, wherein an output of the second switch is connected to a power amplifier path comprising at least the power amplifier, while transmitting the first signal; switching between transmitting the first signal and receiving a second signal by switching an input of the first switch and the output of the second switch, wherein an output of the first switch and an input of the second switch are connected to an amplification path comprising at least the first amplifier; and receiving the second signal via at least the first switch, the first amplifier and the second switch, wherein the output of the second switch is disconnected from the power amplifier path while receiving the second signal.

According to another aspect, there is provided a radio transceiver comprising means for transmitting a first signal via at least a first switch, a first amplifier, a second switch and a power amplifier, wherein an output of the second switch is connected to a power amplifier path comprising at least the power amplifier, while transmitting the first signal; switching between transmitting the first signal and receiving a second signal by switching an input of the first switch and the output of the second switch, wherein an output of the first switch and an input of the second switch are connected to an amplification path comprising at least the first amplifier; and receiving the second signal via at least the first switch, the first amplifier and the second switch, wherein the output of the second switch is disconnected from the power amplifier path while receiving the second signal.

According to another aspect, there is provided an apparatus comprising at least one processor, and at least one memory including computer program code, wherein the at least one memory and the computer program code are configured, with the at least one processor, to cause the apparatus to: transmit a first signal via at least a first switch, a first amplifier, a second switch and a power amplifier, wherein an output of the second switch is connected to a power amplifier path comprising at least the power amplifier, while transmitting the first signal; switch between transmitting the first signal and receiving a second signal by switching an input of the first switch and the output of the second switch, wherein an output of the first switch and an input of the second switch are connected to an amplification path comprising at least the first amplifier; and receive the second signal via at least the first switch, the first amplifier and the second switch, wherein the output of the second switch is disconnected from the power amplifier path while receiving the second signal.

According to another aspect, there is provided a system configured to transmit a first signal via at least a first switch, a first amplifier, a second switch and a power amplifier, wherein an output of the second switch is connected to a power amplifier path comprising at least the power amplifier, while transmitting the first signal; switch between transmitting the first signal and receiving a second signal by switching an input of the first switch and the output of the second switch, wherein an output of the first switch and an input of the second switch are connected to an amplification path comprising at least the first amplifier; and receive the second signal via at least the first switch, the first amplifier and the second switch, wherein the output of the second switch is disconnected from the power amplifier path while receiving the second signal.

According to another aspect, there is provided a method comprising transmitting a first signal via at least a first switch, a first amplifier, a second switch and a power amplifier, wherein an output of the second switch is connected to a power amplifier path comprising at least the power amplifier, while transmitting the first signal; switching between transmitting the first signal and receiving a second signal by switching an input of the first switch and the output of the second switch, wherein an output of the first switch and an input of the second switch are connected to an amplification path comprising at least the first amplifier; and receiving the second signal via at least the first switch, the first amplifier and the second switch, wherein the output of the second switch is disconnected from the power amplifier path while receiving the second signal.

According to another aspect, there is provided a computer program comprising instructions for causing an apparatus such as a radio transceiver to perform at least the following: transmit a first signal via at least a first switch, a first amplifier, a second switch and a power amplifier, wherein an output of the second switch is connected to a power amplifier path comprising at least the power amplifier, while transmitting the first signal; switch between transmitting the first signal and receiving a second signal by switching an input of the first switch and the output of the second switch, wherein an output of the first switch and an input of the second switch are connected to an amplification path comprising at least the first amplifier; and receive the second signal via at least the first switch, the first amplifier and the second switch, wherein the output of the second switch is disconnected from the power amplifier path while receiving the second signal.

According to another aspect, there is provided a computer readable medium comprising program instructions for causing an apparatus to perform at least the following: transmit a first signal via at least a first switch, a first amplifier, a second switch and a power amplifier, wherein an output of the second switch is connected to a power amplifier path comprising at least the power amplifier, while transmitting the first signal; switch between transmitting the first signal and receiving a second signal by switching an input of the first switch and the output of the second switch, wherein an output of the first switch and an input of the second switch are connected to an amplification path comprising at least the first amplifier; and receive the second signal via at least the first switch, the first amplifier and the second switch, wherein the output of the second switch is disconnected from the power amplifier path while receiving the second signal.

According to another aspect, there is provided a non-transitory computer readable medium comprising program instructions for causing an apparatus to perform at least the following: transmit a first signal via at least a first switch, a first amplifier, a second switch and a power amplifier, wherein an output of the second switch is connected to a power amplifier path comprising at least the power amplifier, while transmitting the first signal; switch between transmitting the first signal and receiving a second signal by switching an input of the first switch and the output of the second switch, wherein an output of the first switch and an input of the second switch are connected to an amplification path comprising at least the first amplifier; and receive the second signal via at least the first switch, the first amplifier and the second switch, wherein the output of the second switch is disconnected from the power amplifier path while receiving the second signal.

### BRIEF DESCRIPTION OF THE DRAWINGS

In the following, various exemplary embodiments will be described in greater detail with reference to the accompanying drawings, in which

FIG. 1 illustrates an exemplary embodiment of a cellular communication network;

FIGS. 2a and 2b illustrate a schematic block diagram according to an exemplary embodiment;

FIG. 3 illustrates a flow chart according to an exemplary embodiment;

FIG. 4 illustrates a schematic block diagram according to an exemplary embodiment;

FIG. 5 illustrates a flow chart according to an exemplary embodiment;

FIGS. 6a and 6b illustrate a schematic block diagram according to an exemplary embodiment;

FIG. 7 illustrates a flow chart according to an exemplary embodiment;

FIGS. 8a, 8b and 9 illustrate schematic block diagrams according to some exemplary embodiments;

FIGS. 10 and 11 illustrate flow charts according to some exemplary embodiments;

FIGS. 12a, 12b, 13a and 13b illustrate schematic block diagrams according to some exemplary embodiments;

FIG. 14 illustrates a flow chart according to an exemplary embodiment;

FIGS. 15a, 15b, 16a, 16b, 17 and 18 illustrate schematic block diagrams according to some exemplary embodiments;

FIG. 19 illustrates an apparatus according to an exemplary embodiment.

### DETAILED DESCRIPTION

The following embodiments are exemplifying. Although the specification may refer to “an”, “one”, or “some” embodiment(s) in several locations of the text, this does not necessarily mean that each reference is made to the same embodiment(s), or that a particular feature only applies to a single embodiment. Single features of different embodiments may also be combined to provide other embodiments.

In the following, different exemplary embodiments will be described using, as an example of an access architecture to which the exemplary embodiments may be applied, a radio access architecture based on long term evolution advanced (LTE Advanced, LTE-A) or new radio (NR, 5G), without restricting the exemplary embodiments to such an architecture, however. It is obvious for a person skilled in the art that the exemplary embodiments may also be applied to other kinds of communications networks having suitable means by adjusting parameters and procedures appropriately. Some examples of other options for suitable systems may be the universal mobile telecommunications system (UMTS) radio access network (UTRAN or E-UTRAN), long term evolution (LTE, the same as E-UTRA), wireless local area network (WLAN or Wi-Fi), worldwide interoperability for microwave access (WiMAX), Bluetooth®, personal communications services (PCS), ZigBee®, wideband code division multiple access (WCDMA), systems using ultra-wideband (UWB) technology, sensor networks, mobile ad-hoc networks (MANETs) and Internet Protocol multimedia subsystems (IMS) or any combination thereof.

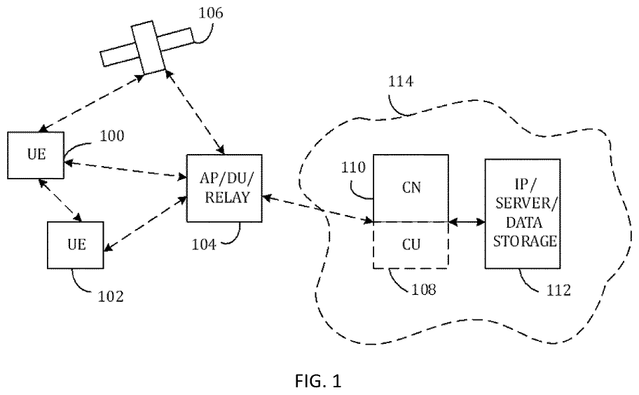

FIG. 1 depicts examples of simplified system architectures showing some elements and functional entities, all being logical units, whose implementation may differ from what is shown. The connections shown in FIG. 1 are logical connections; the actual physical connections may be different. It is apparent to a person skilled in the art that the system may also comprise other functions and structures than those shown in FIG. 1.

The exemplary embodiments are not, however, restricted to the system given as an example but a person skilled in the art may apply the solution to other communication systems provided with necessary properties.

The example of FIG. 1 shows a part of an exemplifying radio access network.

FIG. 1 shows user devices 100 and 102 configured to be in a wireless connection on one or more communication channels in a cell with an access node (such as (e/g)NodeB) 104 providing the cell. The physical link from a user device to a (e/g)NodeB may be called uplink or reverse link and the physical link from the (e/g)NodeB to the user device may be called downlink or forward link. It should be appreciated that (e/g)NodeBs or their functionalities may be implemented by using any node, host, server or access point etc. entity suitable for such a usage.

A communication system may comprise more than one (e/g)NodeB, in which case the (e/g)NodeBs may also be configured to communicate with one another over links, wired or wireless, designed for the purpose. These links may be used for signaling purposes. The (e/g)NodeB may be a computing device configured to control the radio resources of communication system it is coupled to. The NodeB may also be referred to as a base station, an access point or any other type of interfacing device including a relay station capable of operating in a wireless environment. The (e/g)NodeB may include or be coupled to transceivers. From the transceivers of the (e/g)NodeB, a connection may be provided to an antenna unit that establishes bi-directional radio links to user devices. The antenna unit may comprise a plurality of antennas or antenna elements. The (e/g)NodeB may further be connected to core network 110 (CN or next generation core NGC). Depending on the system, the counterpart on the CN side may be a serving gateway (S-GW, routing and forwarding user data packets), packet data network gateway (P-GW), for providing connectivity of user devices (UEs) to external packet data networks, or mobile management entity (MME), etc.

The user device (also called UE, user equipment, user terminal, terminal device, etc.) illustrates one type of an apparatus to which resources on the air interface may be allocated and assigned, and thus any feature described herein with a user device may be implemented with a corresponding apparatus, such as a relay node. An example of such a relay node may be a layer 3 relay (self-backhauling relay) towards the base station.

The user device may refer to a portable computing device that includes wireless mobile communication devices operating with or without a subscriber identification module (SIM), including, but not limited to, the following types of devices: a mobile station (mobile phone), smartphone, personal digital assistant (PDA), handset, device using a wireless modem (alarm or measurement device, etc.), laptop and/or touch screen computer, tablet, game console, notebook, and multimedia device. It should be appreciated that a user device may also be a nearly exclusive uplink only device, of which an example may be a camera or video camera loading images or video clips to a network. A user device may also be a device having capability to operate in Internet of Things (IoT) network which is a scenario in which objects may be provided with the ability to transfer data over a network without requiring human-to-human or human-to-computer interaction. The user device may also utilize cloud. In some applications, a user device may comprise a small portable device with radio parts (such as a watch, earphones or eyeglasses) and the computation may be carried out in the cloud. The user device (or in some exemplary embodiments a layer 3 relay node) may be configured to perform one or more of user equipment functionalities. The user device may also be called a subscriber unit, mobile station, remote terminal, access terminal, user terminal, terminal device, or user equipment (UE) just to mention but a few names or apparatuses.

Various techniques described herein may also be applied to a cyber-physical system (CPS) (a system of collaborating computational elements controlling physical entities). CPS may enable the implementation and exploitation of massive amounts of interconnected ICT devices (sensors, actuators, processors microcontrollers, etc.) embedded in physical objects at different locations. Mobile cyber physical systems, in which the physical system in question may have inherent mobility, are a subcategory of cyber-physical systems. Examples of mobile physical systems include mobile robotics and electronics transported by humans or animals.

Additionally, although the apparatuses have been depicted as single entities, different units, processors and/or memory units (not all shown in FIG. 1) may be implemented.

5G may enable using multiple input-multiple output (MIMO) antennas, many more base stations or nodes than the LTE (a so-called small cell concept), including macro sites operating in co-operation with smaller stations and employing a variety of radio technologies depending on service needs, use cases and/or spectrum available. 5G mobile communications may support a wide range of use cases and related applications including video streaming, augmented reality, different ways of data sharing and various forms of machine type applications (such as (massive) machine-type communications (mMTC), including vehicular safety, different sensors and real-time control. 5G may be expected to have multiple radio interfaces, namely below 6 GHz, cmWave and mmWave, and also being integradable with existing legacy radio access technologies, such as the LTE. Integration with the LTE may be implemented, at least in the early phase, as a system, where macro coverage may be provided by the LTE, and 5G radio interface access may come from small cells by aggregation to the LTE. In other words, 5G may support both inter-RAT operability (such as LTE-5G) and inter-RI operability (inter-radio interface operability, such as below 6 GHz-cmWave, below 6 GHz-cmWave-mmWave). One of the concepts considered to be used in 5G networks may be network slicing in which multiple independent and dedicated virtual sub-networks (network instances) may be created within the same infrastructure to run services that have different requirements on latency, reliability, throughput and mobility.

The current architecture in LTE networks may be fully distributed in the radio and fully centralized in the core network. The low latency applications and services in 5G may require to bring the content close to the radio which leads to local break out and multi-access edge computing (MEC). 5G may enable analytics and knowledge generation to occur at the source of the data. This approach may require leveraging resources that may not be continuously connected to a network such as laptops, smartphones, tablets and sensors. MEC may provide a distributed computing environment for application and service hosting. It may also have the ability to store and process content in close proximity to cellular subscribers for faster response time. Edge computing may cover a wide range of technologies such as wireless sensor networks, mobile data acquisition, mobile signature analysis, cooperative distributed peer-to-peer ad hoc networking and processing also classifiable as local cloud/fog computing and grid/mesh computing, dew computing, mobile edge computing, cloudlet, distributed data storage and retrieval, autonomic self-healing networks, remote cloud services, augmented and virtual reality, data caching, Internet of Things (massive connectivity and/or latency critical), critical communications (autonomous vehicles, traffic safety, real-time analytics, time-critical control, healthcare applications).

The communication system may also be able to communicate with other networks, such as a public switched telephone network or the Internet 112, or utilize services provided by them. The communication network may also be able to support the usage of cloud services, for example at least part of core network operations may be carried out as a cloud service (this is depicted in FIG. 1 by “cloud” 114). The communication system may also comprise a central control entity, or a like, providing facilities for networks of different operators to cooperate for example in spectrum sharing.

Edge cloud may be brought into radio access network (RAN) by utilizing network function virtualization (NVF) and software defined networking (SDN). Using edge cloud may mean access node operations to be carried out, at least partly, in a server, host or node operationally coupled to a remote radio head or base station comprising radio parts. It may also be possible that node operations will be distributed among a plurality of servers, nodes or hosts. Application of cloudRAN architecture may enable RAN real time functions being carried out at the RAN side (in a distributed unit, DU 104) and non-real time functions being carried out in a centralized manner (in a centralized unit, CU 108).

It should also be understood that the distribution of labour between core network operations and base station operations may differ from that of the LTE or even be non-existent. Some other technology advancements that may be used may be Big Data and all-IP, which may change the way networks are being constructed and managed. 5G (or new radio, NR) networks may be designed to support multiple hierarchies, where MEC servers may be placed between the core and the base station or nodeB (gNB). It should be appreciated that MEC may be applied in 4G networks as well.

5G may also utilize satellite communication to enhance or complement the coverage of 5G service, for example by providing backhauling. Possible use cases may be providing service continuity for machine-to-machine (M2M) or Internet of Things (IoT) devices or for passengers on board of vehicles, or ensuring service availability for critical communications, and future railway/maritime/aeronautical communications. Satellite communication may utilize geostationary earth orbit (GEO) satellite systems, but also low earth orbit (LEO) satellite systems, in particular mega-constellations (systems in which hundreds of (nano)satellites are deployed). Each satellite 106 in the mega-constellation may cover several satellite-enabled network entities that create on-ground cells. The on-ground cells may be created through an on-ground relay node 104 or by a gNB located on-ground or in a satellite.

It is obvious for a person skilled in the art that the depicted system is only an example of a part of a radio access system and in practice, the system may comprise a plurality of (e/g)NodeBs, the user device may have an access to a plurality of radio cells and the system may also comprise other apparatuses, such as physical layer relay nodes or other network elements, etc. At least one of the (e/g)NodeBs or may be a Home(e/g)nodeB. Additionally, in a geographical area of a radio communication system, a plurality of different kinds of radio cells as well as a plurality of radio cells may be provided. Radio cells may be macro cells (or umbrella cells) which may be large cells having a diameter of up to tens of kilometers, or smaller cells such as micro-, femto- or picocells. The (e/g)NodeBs of FIG. 1 may provide any kind of these cells. A cellular radio system may be implemented as a multilayer network including several kinds of cells. In multilayer networks, one access node may provide one kind of a cell or cells, and thus a plurality of (e/g)NodeBs may be required to provide such a network structure.

For fulfilling the need for improving the deployment and performance of communication systems, the concept of “plug-and-play” (e/g)NodeBs may be introduced. A network which may be able to use “plug-and-play” (e/g)Node Bs, may include, in addition to Home (e/g)NodeBs (H(e/g)nodeBs), a home node B gateway, or HNB-GW (not shown in FIG. 1). A HNB Gateway (HNB-GW), which may be installed within an operator's network, may aggregate traffic from a large number of HNBs back to a core network.

In order to meet current and future challenges in mobile radio, such as high data rates, high coverage, low latency, and/or wireless control of large numbers of IoT devices, advanced concepts and systems such as multi-antenna beamforming systems, massive MIMO systems, and/or smart transceiver solutions for IoT devices may be needed on the infrastructure side, especially when taking factors such as power consumption and design complexity into account. The required output power level of the systems and/or subsystems may range, depending on the coverage range, from below 24 dBm for low power systems, such as a local area base station, with no upper limit in output power for wide area base stations on the infrastructure side. Thus, applications such as multi-antenna beamforming systems, massive MIMO systems and/or IoT may benefit from compact and energy efficient transceiver solutions with low complexity, since for example multi-antenna systems and massive MIMO systems comprise a large number of transceivers. A transceiver is a combination of a transmitter, TX, and a receiver, RX.

Some exemplary embodiments may provide a compact and energy efficient transceiver, TRX, concept. Some exemplary embodiments comprise an amplification and filtering line-up, which is commonly used, or shared, for downlink and uplink operation.

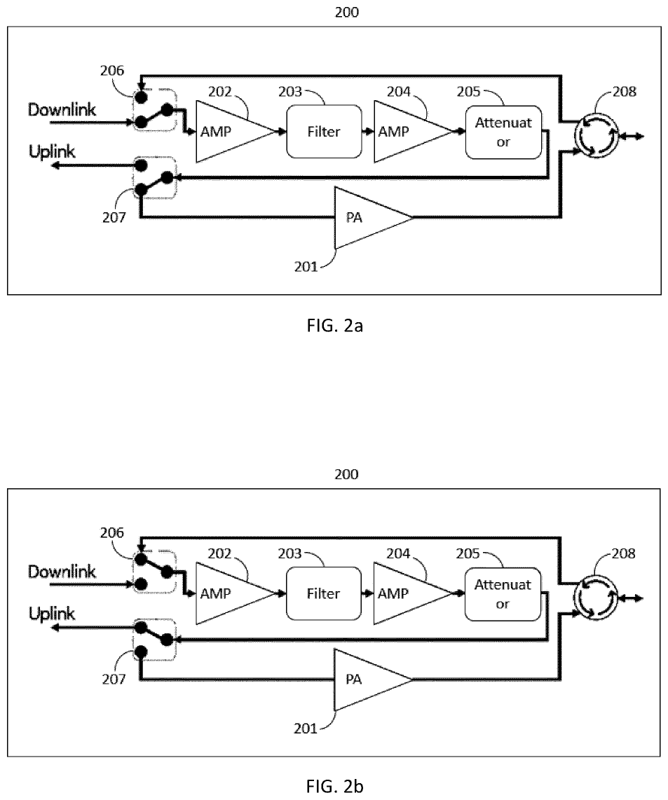

FIGS. 2a and 2b illustrate a transceiver architecture 200 according to an exemplary embodiment. This exemplary embodiment of a transceiver may also be referred to as a high power common transceiver, HPC-TRX, herein. The transceiver may apply time-division duplexing, TDD, wherein transmitting and receiving occur at different time instants. FIG. 2a illustrates the transceiver in transmit, i.e. downlink, operation mode, and FIG. 2b illustrates the transceiver in receive, i.e. uplink, operation mode. A TX power amplifier, PA, 201 is used during downlink operation to amplify a transmit signal in order to provide high transmit power levels. As a non-limiting example, at a 3-4 GHz frequency range, a transmit power level with a peak of 5 W or more may be considered as a high transmit power level. However, what is considered as a high transmit power level may vary depending on the frequency range that is used, for example. The TX power amplifier may be, for example, a Doherty amplifier or any other power amplifier type.

A common amplification line-up comprising a first amplifier, AMP, 202, a filter 203, a second amplifier 204 and an attenuator 205 is used both during downlink and uplink operation. During uplink operation, the common amplification line-up may be used to amplify a receive signal. It should be noted that the order and/or number of the components in the common amplification line-up may vary. The common amplification line-up may further comprise other types of components, such as a phase shifter. The common amplification line-up may be designed for uplink performance, such as a low noise figure, since it may be acting as a pre-amplifier line-up in case of downlink operation. For downlink operation, the common amplifier line-up may be used to provide a sufficient output power to control the TX power amplifier linearly. The gain of the TX power amplifier may be, for example, a design parameter, which may help to optimize the common amplifier line-up for both uplink and downlink operation requirements. The first amplifier 202 and the second amplifier 204 may be, for example, low noise amplifiers, gain blocks, or variable gain amplifiers, and they may be realized with semiconductor technologies such as gallium nitride, GaN, gallium arsenide, GaAs, or laterally-diffused metal-oxide semiconductor, LDMOS. The first amplifier and the second amplifier may also be different amplifier types. For example, the first amplifier may be a low noise amplifier, and the second amplifier may be a variable gain amplifier.

The transceiver further comprises a first switch 206 and a second switch 207, which may be used to switch, or select, between downlink and uplink operation, i.e. between transmitting and receiving. The TX power amplifier 201 may be controlled by switching the second switch 207 such that the RF input signal is provided to the TX power amplifier 201 during downlink operation, but not during uplink operation, since uplink operation may not require as high output power levels as downlink operation.

The transceiver may further comprise a circulator 208 doing separation of TX and RX. Alternatively, the circulator 208 may be substituted by an additional switch that is controlled for TX-RX separation. The circulator 208 or the additional switch may be connected to an antenna, or an antenna array.

In FIG. 2a, the input of the first switch 206 is connected to the downlink path, for example to an up-converter and/or a digital-to-analog converter. The output of the first switch 206 is connected to the common amplification line-up comprising the first amplifier 202, the filter 203, the second amplifier 204, and the attenuator 205. The input of the second switch 207 is connected to the common amplification line-up comprising the first amplifier 202, the filter 203, the second amplifier 204, and the attenuator 205. The output of the second switch 207 is connected to the input of the TX power amplifier 201 while transmitting a signal. The output of the power amplifier 201 is connected to the transmit path, i.e. to the antenna for example via the circulator 208 and/or one or more other components.

In FIG. 2b, the output of the second switch 207 is disconnected from the input of the TX power amplifier 201 while receiving a signal, and thus the TX power amplifier 201 may be idle during uplink operation. The input of the first switch 206 is connected to the receive path from the antenna. The output of the first switch 206 is connected to the common amplification line-up comprising the first amplifier 202, the filter 203, the second amplifier 204, and the attenuator 205. The input of the second switch 207 is connected to the common amplification line-up comprising the first amplifier 202, the filter 203, the second amplifier 204, and the attenuator 205. The output of the second switch 207 is connected to the uplink path, for example to a down-converter and/or an analog-to-digital converter.

In another exemplary embodiment, the common amplification line-up may comprise the first amplifier 202, but not the filter 203, the second amplifier 204 and the attenuator 205.

In some exemplary embodiments, the TX power amplifier may be turned off during uplink operation in order to reduce power consumption and thus improve overall efficiency. For example, a further switch in the bias network of the power amplifier or a controllable/switchable power supply may be used to turn off the power amplifier on the gate side during uplink operation, for example by setting 0V for LDMOS or a deep negative bias for GaN power amplifiers in order to reduce power consumption during uplink operation.

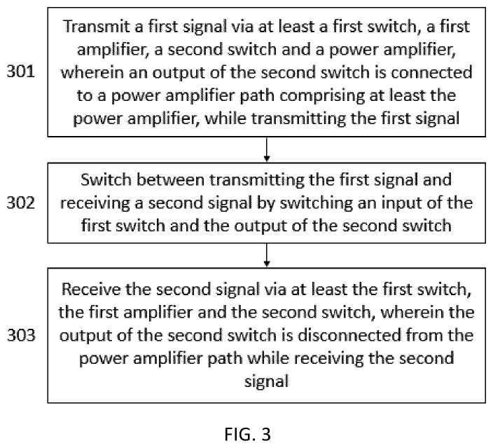

FIG. 3 illustrates a flow chart according to an exemplary embodiment, which may apply for example the architecture 200 illustrated in FIGS. 2a and 2b. A first signal is transmitted 301 via at least a first switch, a first amplifier, a second switch and a power amplifier, wherein an output of the second switch is connected to a power amplifier path comprising at least the power amplifier, while transmitting the first signal. In other words, the output of the second switch may be connected to the power amplifier directly, or via another component such as a driver or a gain block in the power amplifier path. The first signal may be first amplified by at least the first amplifier, and then further amplified by at least the power amplifier. An input of the first switch and the output of the second switch are switched in order to switch 302 between transmitting the first signal and receiving a second signal, wherein an output of the first switch and an input of the second switch are connected to an amplification path comprising at least the first amplifier. In other words, the amplification path is between the first switch and the second switch. The amplification path may further comprise, for example, a filter, a second amplifier and/or an attenuator. The second signal is received 303 via at least the first switch, the first amplifier and the second switch, wherein the output of the second switch is disconnected from the power amplifier path while receiving the second signal. In other words, the received second signal is amplified by at least the first amplifier, but the second signal does not go through the power amplifier.

The functions and/or blocks described above by means of FIG. 3 are in no absolute chronological order, and some of them may be performed simultaneously or in an order differing from the described one. Other functions and/or blocks may also be executed between them or within them.

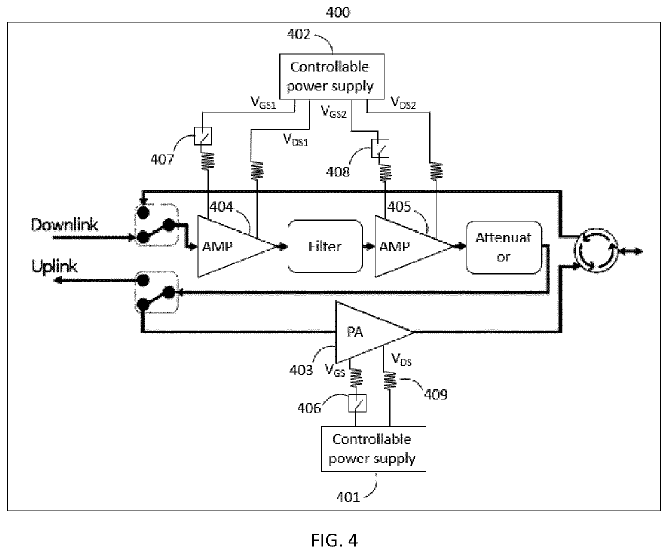

FIG. 4 illustrates an architecture 400 according to an exemplary embodiment, wherein a controllable power supply 401, 402 may be used to turn on/off the power amplifier 403, the first amplifier 404, and/or the second amplifier 405. It may be beneficial to turn off at least the power amplifier 403 during uplink operation in order to reduce power consumption. For example, switches 406, 407, 408 in the gate-to-source voltage feeds may be used for the on/off switching. V_{GS}, V_{GS1} and V_{GS2} denote gate-to-source voltage for the power amplifier 403, the first amplifier 404 and the second amplifier 405, respectively. V_{DS}, V_{DS1} and V_{DS2} denote drain-to-source voltage for the power amplifier 403, the first amplifier 404 and the second amplifier 405, respectively. Furthermore, drain bias voltage control may be applied to the power amplifier 403, the first amplifier 404, and/or the second amplifier 405 during downlink operation in order to adjust the drain voltage and thus the power consumption of the power amplifier 403, the first amplifier 404, and/or the second amplifier 405 during downlink operation based on the actual load situation. This may be used for optimizing power consumption and thus also the overall HPC-TRX efficiency during downlink operation. Optionally, the gate voltage may also be adjusted to optimize the operation point for the new drain voltage. Inductors 409 may be placed in the bias supply feeds for radio frequency, RF, blocking so that no RF signal from the signal path leaks through the bias lines, and that no disturbance from the direct current, DC, supply is fed into the amplifiers.

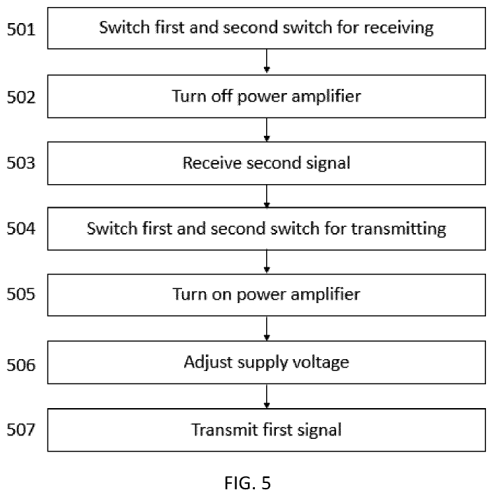

FIG. 5 illustrates a flow chart according to an exemplary embodiment, which may apply for example the architecture 400 illustrated in FIG. 4. The first switch and the second switch are switched 501 to uplink operation, i.e. for receiving. The power amplifier is turned off 502. The second signal is received 503, while the power amplifier is turned off. The first switch and the second switch are switched 504 to downlink operation, i.e. for transmitting. The power amplifier is turned on 505. A supply voltage of the power amplifier, the first amplifier, and/or the second amplifier is adjusted 506. The first signal is transmitted 507, while the power amplifier is turned on.

The functions and/or blocks described above by means of FIG. 5 are in no absolute chronological order, and some of them may be performed simultaneously or in an order differing from the described one. Other functions and/or blocks may also be executed between them or within them.

In another exemplary embodiment, the first amplifier and the second amplifier may also be turned off during uplink operation, for example in case of high receive signal levels, which may not require that much receive amplification. If the first amplifier and the second amplifier have been turned off during uplink operation, the first amplifier and the second amplifier are turned on during downlink operation.

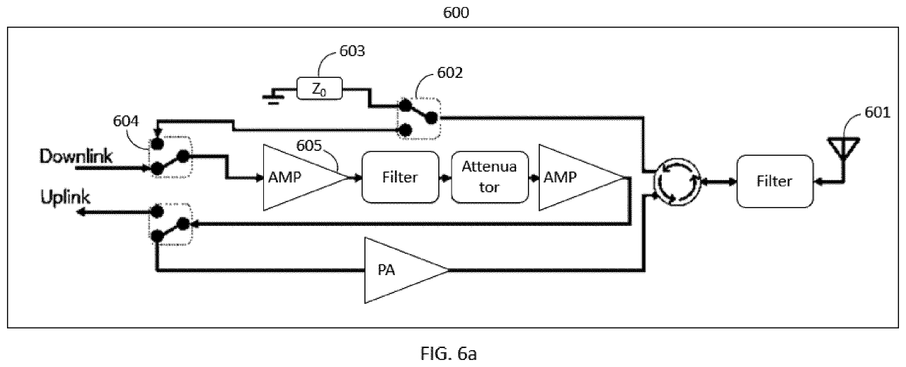

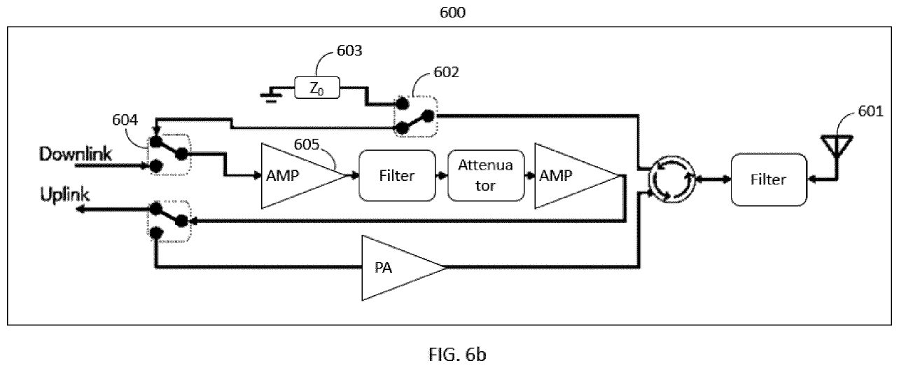

FIGS. 6a and 6b illustrate a transceiver architecture 600 according to another exemplary embodiment. The transceiver may apply time-division duplexing, TDD. FIG. 6a illustrates the transceiver in downlink operation, and FIG. 6b illustrates the transceiver in uplink operation. A third switch 602 may be connected to a termination 603 from one of the output ports of the third switch 602. The third switch 602 is added to the receive path in order to improve downlink self-interference suppression. This way, the receive path from the antenna 601 may be terminated by the third switch 602 switching to the termination 603 during downlink operation. In case of uplink operation, the third switch 602 is switched such that the receive signal from the antenna 601 is directed via the third switch 602 to the input of the first switch 604, thereby providing the received low level signal to the input of the first amplifier 605 and thus to the common amplification line-up. The termination 603 may also be referred to as a terminating resistor or a terminator. The impedance Zo of the termination 603 may be at least 50 ohms, as a non-limiting example.

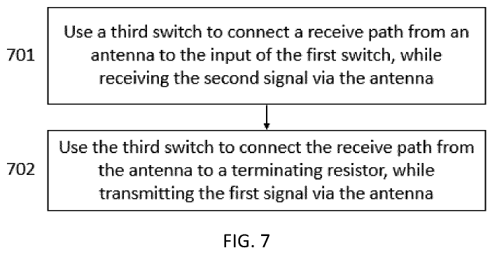

FIG. 7 illustrates a flow chart according to an exemplary embodiment, which may apply for example the architecture 600 illustrated in FIGS. 6a and 6b. A third switch is used 701 to connect a receive path from an antenna to the input of the first switch, while receiving the second signal via the antenna. The third switch is used 702 to connect the receive path from the antenna to a terminating resistor, while transmitting the first signal via the antenna.

The functions and/or blocks described above by means of FIG. 7 are in no absolute chronological order, and some of them may be performed simultaneously or in an order differing from the described one. Other functions and/or blocks may also be executed between them or within them.

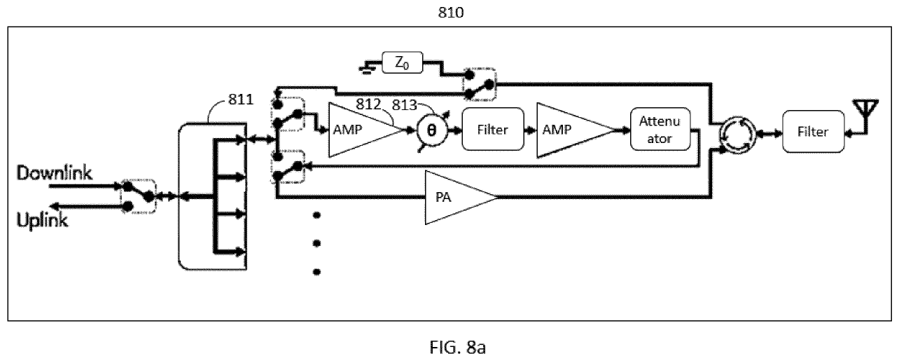

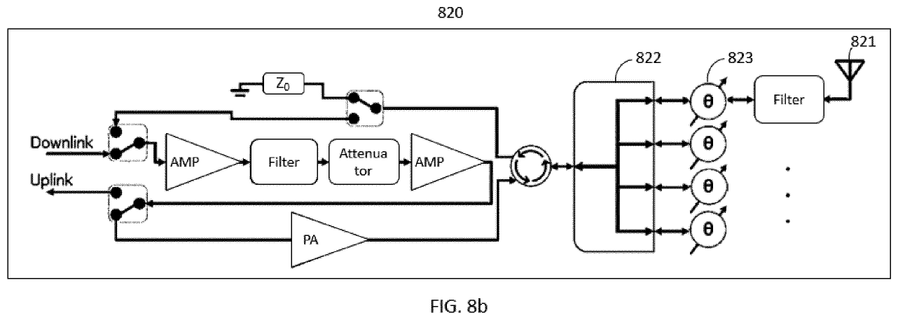

FIGS. 2a, 2b, 6a and 6b illustrate a single TRX path. However, the HPC-TRX 200, 600 may also be applied for example to hybrid multi-antenna systems. FIGS. 8a and 8b illustrate architectures 810, 820 according to two exemplary embodiments, wherein the HPC-TRX is applied to multi-antenna systems.

FIG. 8a illustrates an exemplary embodiment, wherein a plurality of HPC-TRX line-ups are implemented after a splitter 811. In order to enable flexible beamforming, a controllable phase shifter 813 may optionally be placed at the output of the first amplifier 812, for example for each of the HPC-TRX line-ups. However, it is not mandatory to equip each line-up with a controllable phase shifter. If no flexible beam control is required, then for example fixed delay lines for example with different lengths per HPC-TRX may be used instead of the controllable phase shifters to form a fixed beam direction. The phase shifters may also be placed elsewhere in the HPC-TRX line-ups. Instead of a phase shifter, some other phase-shifting component, such as a vector modulator, may also be used to control both phase and amplitude.

FIG. 8b illustrates an exemplary embodiment, wherein a single HPC-TRX line-up is feeding several antennas 821. Thus, the splitter 822 is placed at the output, i.e. downlink direction, of the HPC-TRX, and controllable phase shifters 823 per individual antenna may optionally be placed at the output of each splitting path, i.e. TX direction, of the splitter 822. If no flexible beam control is required, then for example fixed delay lines for example with different lengths per antenna may alternatively be used instead of the controllable phase shifters to form a fixed beam direction. Instead of a phase shifter, some other phase-shifting component, such as a vector modulator, may also be used to control both phase and amplitude.

The exemplary embodiment of FIG. 8a may be beneficial for minimizing the output losses at the HPC-TRX line-up towards the antenna, while the exemplary embodiment of FIG. 8b may be beneficial for reducing circuit complexity and component count. There may also be other variants in addition to these two exemplary embodiments that may be used for hybrid multi-antenna systems. For example, in the architecture 820 the number of antennas per HPC-TRX line-up may vary. In addition, in the architecture 810 the number of HPC-TRXs and antennas per individual TRX conversion path may vary.

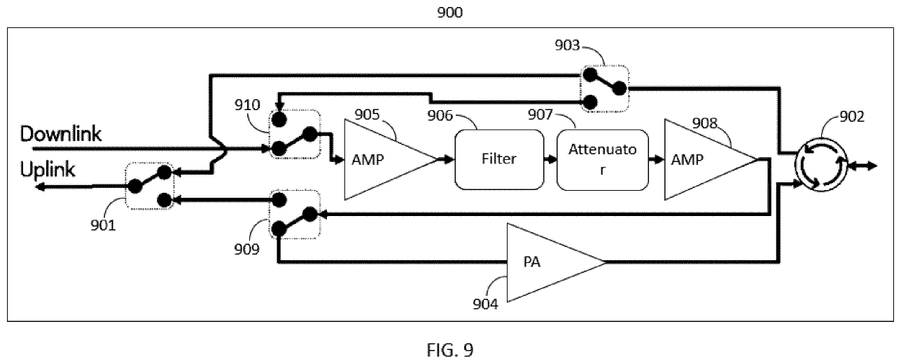

FIG. 9 illustrates an architecture 900 according to another exemplary embodiment, wherein a fourth switch 901 is added to achieve feedback-path, FB, functionality during downlink operation. This may enable adaptive linearization, such as digital predistortion, to be applied in order to improve the linearity, output power and energy efficiency of the power amplifier. Thus, the performance of the full TRX front-end may be improved. During TX operation, the main portion of the signal is transferred by the circulator 902 to the antenna. However, the isolation achieved by the circulator 902 may be limited, and thus a fraction of the transmit signal power, for example 20-25 dB less, may leak to the receive path, which may cause self-interference. However, this signal leakage may be beneficially used and fed back to the uplink down-conversion path by controlling the third switch 903 and the fourth switch 901, and thus used for signal analysis in the digital front-end during downlink operation. By analysing this TX feedback signal, for example digital predistortion may be applied and adapted, and the transmit signal may be predistorted in order to improve the linearity and energy efficiency of the power amplifier 904 also for increased output power levels. An additional attenuator, for example a variable attenuator, may be added to the feedback path, for example between the fourth switch 901 and the third switch 903, in order to adapt the feedback path signal power to a suitable level to be further processed by a down-converter and/or an analog-to-digital converter.

In a first uplink operation mode, in case of low receive signal levels, the received signal may be transferred via the third switch 903 and the first switch 910 to the input of the common TRX amplification line-up comprising the first amplifier 905, filter 906, attenuator 907, and second amplifier 908, but excluding the TX power amplifier 904. By switching the second switch 909 and the fourth switch 901 for receive operation (not shown in FIG. 9), the receive signal may be fed to the down-conversion path. This way, the common amplification line-up may be used to amplify the receive signal in order to feed the receive signal for example to a down-converter and/or an analog-to-digital converter at a suitable power level.

In a second uplink operation mode, in case of high receive power levels not requiring further amplification before down-converting, the third switch 903 may be switched such that the amplifier line-up is bypassed and preferably turned off in order to save energy, and the receive signal is fed directly via the fourth switch 901 to the down-conversion unit for down-converting the receive signal to an intermediate frequency. The power amplifier 904 may be turned off in both uplink operation modes in order to reduce power consumption during uplink operation, and thus improve overall energy efficiency.

Digital predistortion is a linearization technique that may be used to improve the linearity of a power amplifier. In digital predistortion, a predistorter may be used to predistort the input signal that is fed to the power amplifier, for example to modify the amplitude and/or phase of the input signal, and thus reverse the nonlinearity introduced by the power amplifier, given that an accurate model for the nonlinearity of the power amplifier is used. The predistorter may be implemented in the digital baseband domain. Furthermore, adaptive digital predistortion techniques may be used to adjust to changes in the power amplifier model caused for example by aging effects of the power amplifier, and to update the predistorter accordingly. Adaptive digital predistortion may comprise one or more of the following steps: identifying the power amplifier model, estimating the parameters of the identified power amplifier model, and/or estimating the predistortion parameters to be used by the predistorter for inversing the identified power amplifier model.

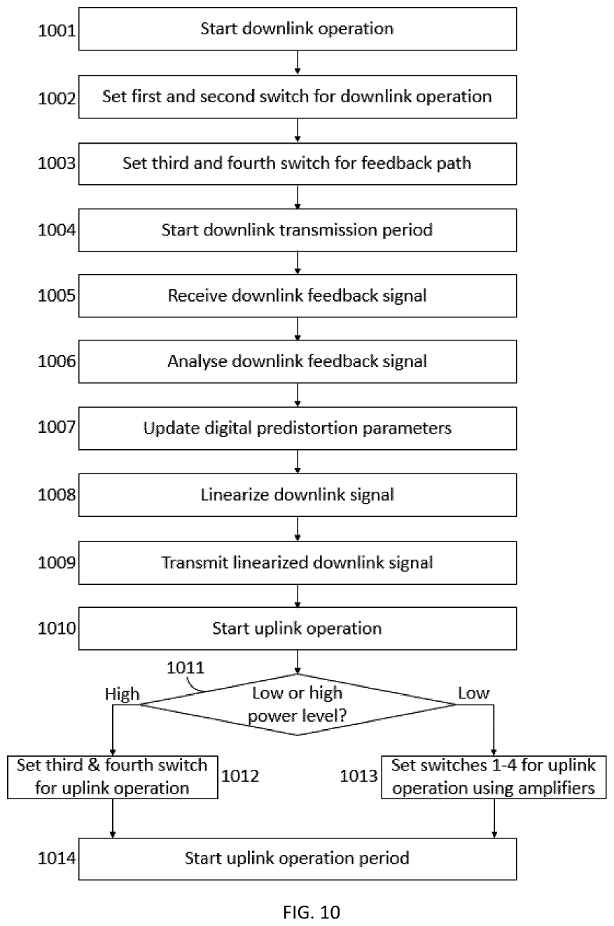

FIG. 10 illustrates a flow chart according to an exemplary embodiment, which may apply for example the transceiver architecture illustrated in FIG. 9. Referring to FIG. 10, downlink operation is started 1001. The first switch and the second switch are set 1002 for downlink operation. The third switch and the fourth switch are set 1003 for the feedback path. The downlink transmission period is started 1004. A downlink feedback signal comprising a portion of the transmitted downlink signal is received 1005 and analysed 1006. Digital predistortion parameters are updated 1007 based on the analysis of the downlink feedback signal. The downlink signal is then linearized 1008 for example by using a digital predistorter to predistort the downlink signal based on the updated digital predistortion parameters. The linearized downlink signal is then transmitted 1009. Uplink operation is started 1010. It is then evaluated 1011 whether the receive signal power level is low or high, for example based on a pre-defined threshold. If the receive signal power level is high (1011: high), then the third switch and the fourth switch are set 1012 for uplink operation, and the uplink operation period is started 1014. If the receive signal power level is low (1011: low), then the first switch, the second switch, the third switch and the fourth switch are set 1013 for uplink operation using amplifiers, and the uplink operation period is started 1014.

The functions and/or blocks described above by means of FIG. 10 are in no absolute chronological order, and some of them may be performed simultaneously or in an order differing from the described one. Other functions and/or blocks may also be executed between them or within them.

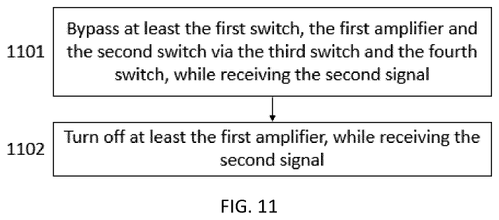

FIG. 11 illustrates a flow chart according to an exemplary embodiment, which may apply for example the second uplink operation mode of the transceiver architecture illustrated in FIG. 9. At least the first switch, the first amplifier and the second switch are bypassed 1101 via the third switch and the fourth switch, while receiving the second signal. At least the first amplifier is turned off 1102, while receiving the second signal.

The functions and/or blocks described above by means of FIG. 11 are in no absolute chronological order, and some of them may be performed simultaneously or in an order differing from the described one. Other functions and/or blocks may also be executed between them or within them.

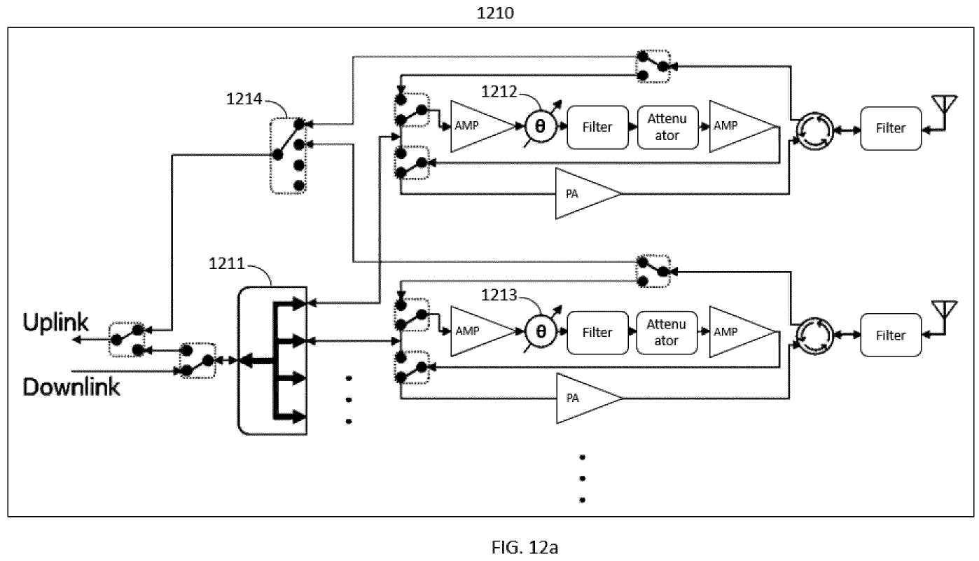

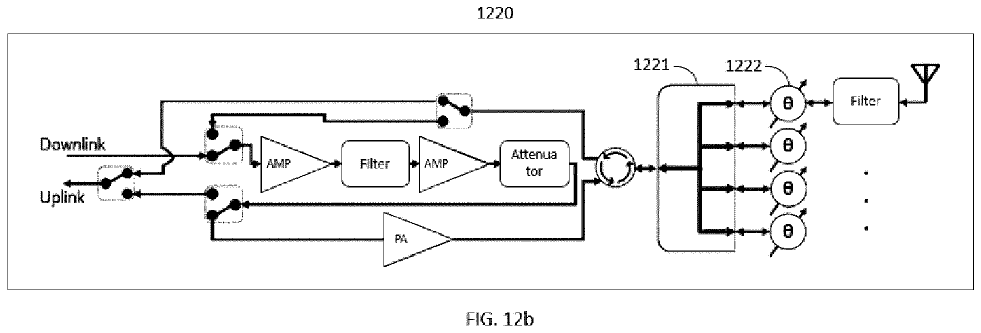

FIGS. 12a and 12b illustrate architectures 1210, 1220 according to two exemplary embodiments, wherein an HPC-TRX with a feedback path is applied for example in a hybrid multi-antenna system.

FIG. 12a illustrates an exemplary embodiment, wherein a plurality of full HPC-TRX line-ups are placed at the output of the splitter 1211, and each HPC-TRX may optionally comprise a controllable phase shifter 1212, 1213. If no flexible beam control is required, then for example fixed delay lines for example with different lengths per HPC-TRX may alternatively be used instead of the controllable phase shifters to form a fixed beam direction. The phase shifters may also be placed elsewhere in the HPC-TRX line-ups. Instead of a phase shifter, some other phase-shifting component, such as a vector modulator, may also be used to control both phase and amplitude. In order to support flexible feedback-path operation for monitoring individual power amplifier distortions, an additional multi-pole switch 1214 or a combiner is used to select the respective feedback path of the power amplifier, which is to be fed back and monitored. The feedback signal of each power amplifier may be multiplexed either in the same TX period or in distinct transmission cycles.

FIG. 12b illustrates an exemplary embodiment, wherein a single HPC-TRX is placed at the input of the splitter 1221. Controllable phase shifters 1222 may optionally be placed on the output paths of the splitter for individual antenna phase control. If no flexible beam control is required, then for example fixed delay lines for example with different lengths per antenna may alternatively be used instead of the controllable phase shifters to form a fixed beam direction. Instead of a phase shifter, some other phase-shifting component, such as a vector modulator, may also be used to control both phase and amplitude.

The exemplary embodiment of FIG. 12a may reduce insertion losses at the output of the HPC-TRX in TX direction, while the exemplary embodiment of FIG. 12b may reduce component count.

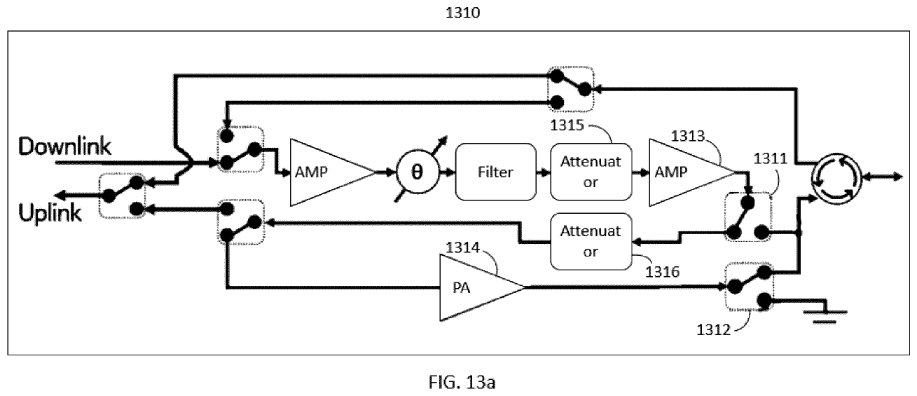

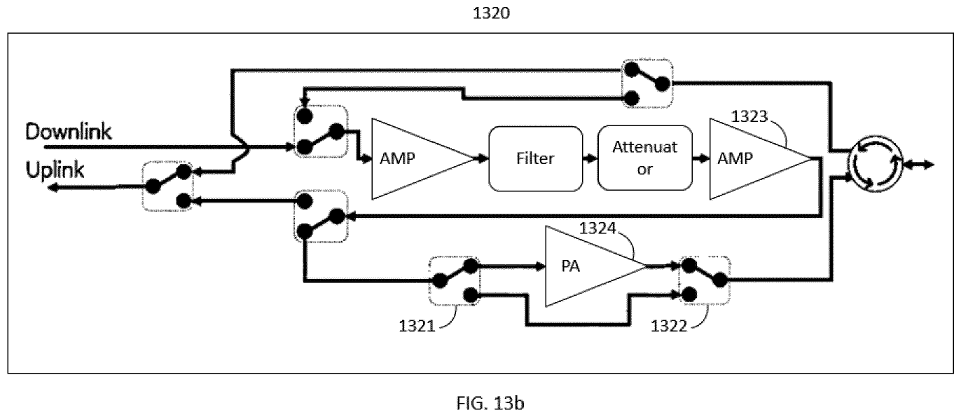

FIGS. 13a and 13b illustrate architectures 1310, 1320 according to two exemplary embodiments, wherein a capability for bypassing the final power amplifier 1314, 1324 during downlink operation is provided by a fifth switch 1311, 1321 and a sixth switch 1312, 1322. Bypassing the final power amplifier during downlink operation may be useful for example in case of low load operation, since the power amplifier may be turned off, and the second amplifier 1313, 1323 may then act as the final amplifier. This way, the efficiency may be improved in case of a low load situation compared to when the power amplifier would still be in operation but in deep backoff mode.

The exemplary embodiment illustrated in FIG. 13a may reduce insertion loss at the output of the second amplifier 1313 in order to improve efficiency in case of a low load situation, when the second amplifier 1313 acts as the final amplification stage. The first attenuator 1315 before the second amplifier 1313 may be omitted, for example when using a variable-gain amplifier, or when the dynamic range of a digital-to-analog converter provides sufficient range to control the amplitude/power of the transmitted signal. Furthermore, in addition to the second attenuator 1316, one or more additional components may also be added to the common amplification path for the power amplifier and for the uplink operation.

The exemplary embodiment illustrated in FIG. 13b may reduce self-interference in case of downlink operation, since TX signal back-coupling via the fifth switch 1321 may be avoided compared to the exemplary embodiment of FIG. 13a. However, the insertion loss at the output of the second amplifier 1323 may be increased by the insertion loss of the sixth switch 1322 compared to the exemplary embodiment of FIG. 13a.

While both architectures 1310, 1320 of FIGS. 13a and 13b may improve efficiency in low load situations, in FIG. 13a the downlink signal only needs to pass one switch after the second amplifier's 1313 output to the antenna. Thus, the architecture 1310 of FIG. 13a may further improve efficiency compared to the architecture 1320 of FIG. 13b, but possibly at the expense of higher downlink self-interference compared to FIG. 13b.

If the HPC-TRX comprises a feedback path and a possibility to bypass the power amplifier during downlink operation, then the second amplifier in the common TRX amplification line-up may be linearized for example by using digital predistortion, while being the final amplifier stage in case of a low load situation and using the power amplifier bypassing. The signal from the second amplifier may thus be fed back to the digital front-end unit.

It should be noted that the feedback path is optional in the HPC-TRX 1310, 1320, and some exemplary embodiments may provide a capability to bypass the final power amplifier without comprising a feedback path.

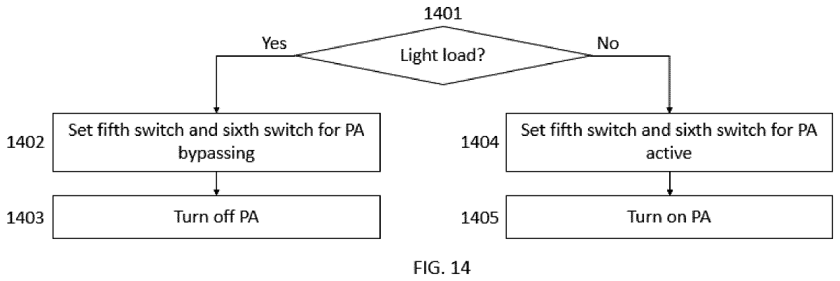

FIG. 14 illustrates a flow chart according to an exemplary embodiment, which may apply for example the architecture illustrated in FIG. 13a or 13b. Referring to FIG. 14, it is determined 1401 if the load is light. For example, a pre-defined threshold may be used to determine whether the load is light or not. There may be a break-even point up to which bypassing the power amplifier is more efficient compared to operating the power amplifier, and this break-even point may be used as the threshold, for example.

Herein the load may refer, for example, to the degree of capacity of the cell which is supported by this exemplary embodiment. The load situation may depend, for example, on the actual number of users and required data rates. For example, if during night-time there is only a low number of users requiring low data rates, then that may be defined as a low load situation. On the other hand, if there are a lot of users requiring high data rates for example during daytime, then that may be defined as a high load situation or even a full load situation. Thus, depending on how much transmit power is needed to serve the users and the data throughput situation, PA bypassing may be activated or deactivated.

If the load is light (1401: yes), the fifth switch and the sixth switch are set 1402 to bypass the power amplifier, and the power amplifier is turned off 1403. If the load is not light (1401: no), i.e. the load is medium or heavy, the fifth switch and sixth switch are set 1404 to connect the power amplifier for signal transmission, and the power amplifier is turned on 1405. The process may be iterative such that, when the load situation changes after block 1403 or 1405, the process may return to block 1401.

The functions and/or blocks described above by means of FIG. 14 are in no absolute chronological order, and some of them may be performed simultaneously or in an order differing from the described one. Other functions and/or blocks may also be executed between them or within them.

The HPC-TRX 1310, 1320 with a capability to bypass the final power amplifier may also be applied for example in a hybrid multi-antenna system.

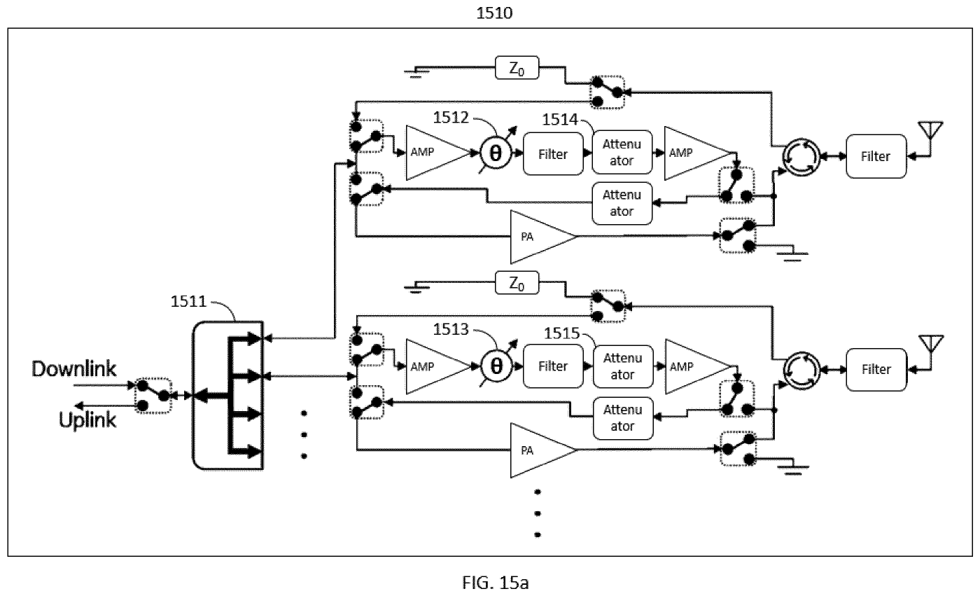

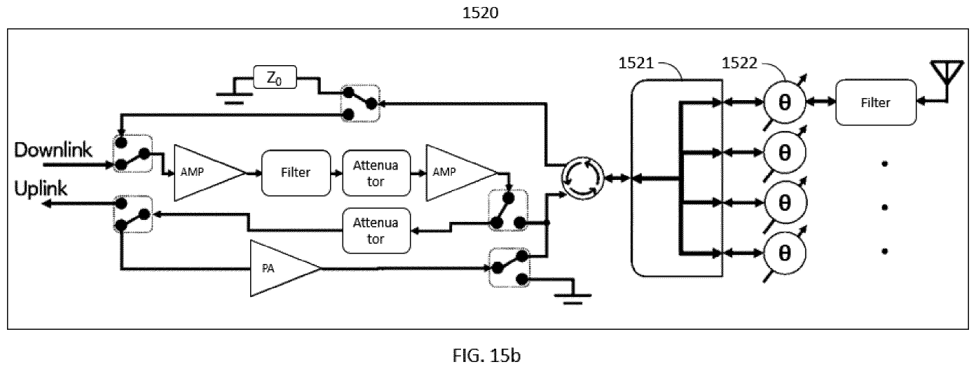

FIGS. 15a and 15b illustrate architectures 1510, 1520 according to two exemplary embodiments, wherein an HPC-TRX with a capability to bypass the final power amplifier during downlink operation is applied for example in a hybrid multi-antenna system.

In the exemplary embodiment illustrated in FIG. 15a, a plurality of HPC-TRX line-ups with a capability to bypass the final power amplifier during downlink operation are placed after the splitter 1511, thus reducing insertion loss at the output of each HPC-TRX, and a controllable phase shifter 1512, 1513 may optionally be placed into each HPC-TRX for example after the first amplifier, as illustrated in FIG. 15a. The phase shifter 1512, 1513 may also be placed elsewhere in the common amplification path, for example after the attenuator 1514, 1515. If no flexible beam control is required, then for example fixed delay lines for example with different lengths per HPC-TRX may be used instead of the controllable phase shifters to form a fixed beam direction. The phase shifters may also be placed elsewhere in the HPC-TRX line-ups. Instead of a phase shifter, some other phase-shifting component, such as a vector modulator, may also be used to control both phase and amplitude.

In the exemplary embodiment illustrated in FIG. 15b, a single HPC-TRX with a capability to bypass the final power amplifier during downlink operation is placed before the splitter 1521, thus reducing the complexity and component count. Controllable phase shifters 1522 may optionally be placed on the output paths of the splitter for individual antenna phase control. If no flexible beam control is required, then for example fixed delay lines for example with different lengths per antenna may be used instead of the controllable phase shifters to form a fixed beam direction. Instead of a phase shifter, some other phase-shifting component, such as a vector modulator, may also be used to control both phase and amplitude.

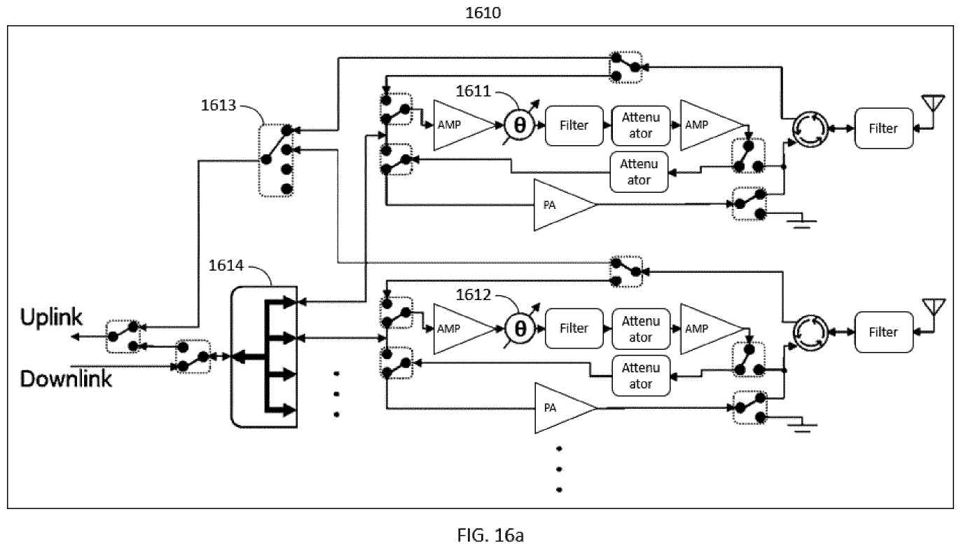

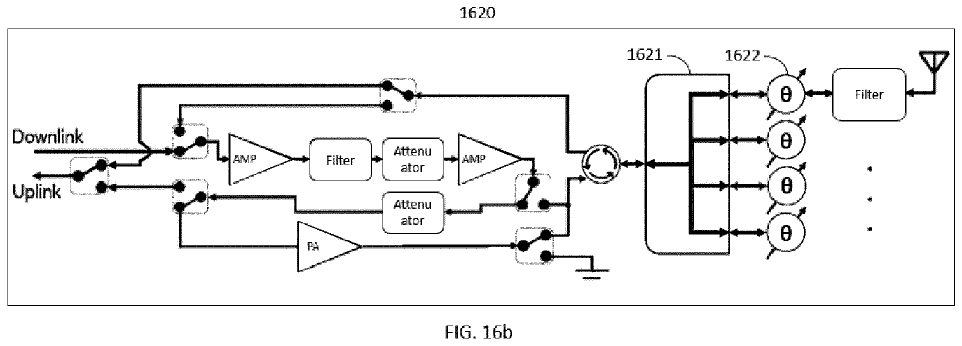

FIGS. 16a and 16b illustrate architectures 1610, 1620 according to two exemplary embodiments, wherein an HPC-TRX line-up 1310 with a capability to bypass the final power amplifier during downlink operation and a feedback path supporting adaptive digital predistortion is applied for example in a hybrid multi-antenna system.

In the exemplary embodiment illustrated in FIG. 16a, a plurality of HPC-TRX line-ups are placed after the splitter 1614, thus reducing insertion loss at the output of each HPC-TRX, and a controllable phase shifter 1611, 1612 may optionally be placed into each HPC-TRX line-up 1310 after the first amplifier. If no flexible beam control is required, then for example fixed delay lines for example with different lengths per HPC-TRX may be used instead of the controllable phase shifters to form a fixed beam direction. The phase shifters may also be placed elsewhere in the HPC-TRX line-ups. Instead of a phase shifter, some other phase-shifting component, such as a vector modulator, may also be used to control both phase and amplitude. In order to support flexible feedback-path operation for monitoring individual power amplifier distortions, an additional multi-pole switch 1613 or a combiner is used to select the respective feedback path of the power amplifier, which is to be fed back and monitored.

In the exemplary embodiment illustrated in FIG. 16b, a single HPC-TRX line-up 1310 is placed before the splitter 1621, thus reducing the complexity and component count. Controllable phase shifters 1622 may optionally be placed on the output paths of the splitter for individual antenna phase control. If no flexible beam control is required, then for example fixed delay lines for example with different lengths per antenna may be used instead of the controllable phase shifters to form a fixed beam direction. Instead of a phase shifter, some other phase-shifting component, such as a vector modulator, may also be used to control both phase and amplitude.

Although not illustrated in FIGS. 16a and 16b, the HPC-TRX line-up 1320 of FIG. 13b may alternatively be used instead of the HPC-TRX line-up 1310 of FIG. 13a in the architectures 1610, 1620 illustrated in FIGS. 16a and 16b.

It should be noted that some of the previously described exemplary embodiments may also be flexibly combined for example based on application requirements. In addition, further variants for hybrid multi-antenna systems may also be possible.

Furthermore, some exemplary embodiments may be applied for example to digital massive multiple input multiple output, mMIMO, or beamforming systems, as well as to systems with a single or low number of TRX paths.

Some exemplary embodiments may also be flexibly combined with different conversion units, such as radio frequency digital-to-analog, RFDAC, and radio frequency analog-to-digital, RFADC, solutions doing digital-to-analog conversion and up-conversion, as well as down-conversion and analog-to-digital conversion, respectively, and also with digital-to-analog and analog-to-digital converters combined with mixers, or digital-to-analog and analog-to-digital converters combined with quadrature modulators. Some exemplary embodiments may also be applicable to heterodyning concepts for example in the millimeter wave, mmWave, or THz range.

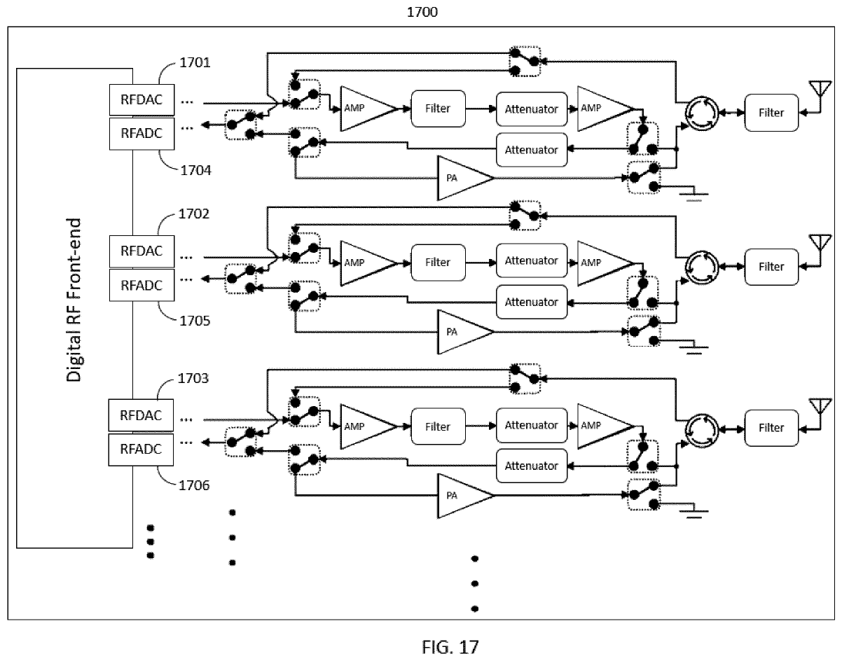

FIG. 17 illustrates an architecture 1700 according to an exemplary embodiment, wherein a plurality of HPC-TRXs are applied to a digital mMIMO system using RFDAC 1701, 1702, 1703 and RFADC 1704, 1705, 1706 for signal conversion.

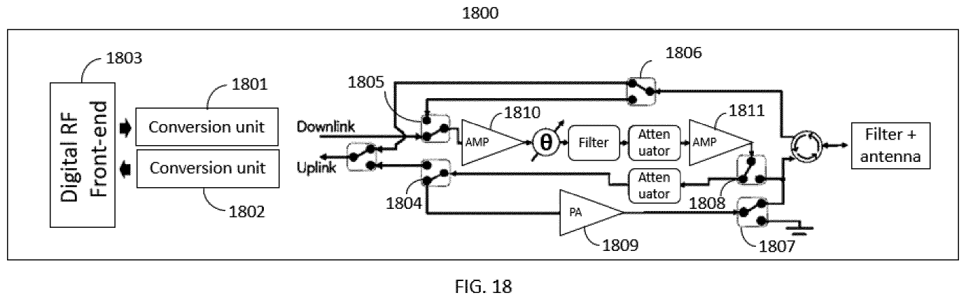

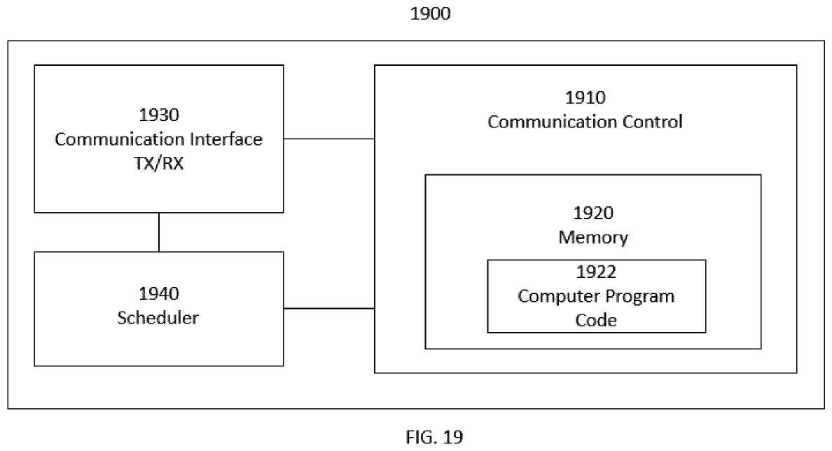

FIG. 18 illustrates an architecture 1800 according to an exemplary embodiment, wherein the HPC-TRX is applied to a digital RF front-end unit 1803 via a first conversion unit 1801 and a second conversion unit 1802. The first conversion 1801 unit may comprise, for example, an RFDAC, a digital-to-analog converter and a modulator, a digital-to-analog converter and a mixer, and/or a heterodyning circuit. The second conversion unit 1802 may comprise, for example, an RFADC, an analog-to-digital converter and a modulator, an analog-to-digital converter and a mixer, and/or a heterodyning circuit.

The digital RF front-end unit 1803 may comprise at least a part of a digital signal processor (DSP), at least a part of an application specific integrated circuit (ASIC), at least a part of a central processing unit (CPU), and/or at least a part of a field programmable gate array (FPGA), for example. The digital RF front-end unit 1803 may perform further signal processing, such as demodulation, detection, and/or decoding, of a receive signal of the HPC-TRX. Moreover, the digital RF front-end unit 1803 may comprise control circuitry for actuating the switches 1804, 1805, 1806, 1807, 1808. Additionally, or alternatively, the digital RF front-end unit 1803 may be configured to adjust a supply voltage of the power amplifier 1809, the first amplifier 1810, and/or the second amplifier 1811. Furthermore, the digital RF front-end unit 1803 may be configured to generate a digital transmit signal of the HPC-TRX. The first conversion unit 1801 coupled to an output-port of the digital RF front-end unit 1803 may transform the digital transmit signal to an analog transmit signal.

It should also be noted that components such as filters and attenuators may be placed in a different sequence, or arrangement, than illustrated in the above exemplary embodiments. Filters and attenuators may also be integrated in a distributed manner, for example by splitting an attenuator with a large attenuation range in two devices with a smaller attenuation range but distributed in the line-up.

A technical advantage provided by some exemplary embodiments may be that they may reduce complexity, design effort, component count, and/or power consumption of radio equipment and systems, such as single-TRX devices, small cell applications with a low number of TRXs, multi-antenna systems, massive MIMO systems, and/or IoT devices. Some exemplary embodiments may be used, for example, in order to meet requirements on data throughput, coverage, and/or latency for example in NR. Some exemplary embodiments may support a wide range of application-specific output power levels, thus also being capable of supporting medium to high output power levels per TRX during downlink operation, while maintaining high receiver performance such as sensitivity and good energy efficiency during uplink operation as well. Furthermore, the feedback path used in some exemplary embodiments may improve the linearity of the TX power amplifier, thus further improving energy efficiency. Moreover, the PA bypassing used in some exemplary embodiments may further improve energy efficiency in low load situations. Some exemplary embodiments may be used for sub 6 GHz frequency bands as well as for mmWave and THz frequency ranges. The transceiver may be implemented for example by using lumped components for example for sub 6 GHz applications on line cards, or as integrated circuits for example in mmWave or THz applications.

The exemplary embodiments described above may be used in an apparatus such as a base station, a terminal device, an IoT device, a relay, a repeater, etc. In other words, the apparatus may comprise an HPC-TRX, i.e. a radio transceiver, according to any of the described exemplary embodiments.

The apparatus 1900 of FIG. 19 illustrates an exemplary embodiment of an apparatus such as, or comprised in, a base station such as a gNB. The apparatus may comprise, for example, a circuitry or a chipset applicable to a base station to realize some of the described exemplary embodiments. The apparatus 1900 may be an electronic device comprising one or more electronic circuitries. The apparatus 1900 may comprise a communication control circuitry 1910 such as at least one processor, and at least one memory 1920 including a computer program code (software) 1922 wherein the at least one memory and the computer program code (software) 1922 are configured, with the at least one processor, to cause the apparatus 1900 to carry out some of the exemplary embodiments described above.

The memory 1920 may be implemented using any suitable data storage technology, such as semiconductor-based memory devices, flash memory, magnetic memory devices and systems, optical memory devices and systems, fixed memory and removable memory. The memory may comprise a configuration database for storing configuration data. For example, the configuration database may store a current neighbour cell list, and, in some exemplary embodiments, structures of the frames used in the detected neighbour cells.

The apparatus 1900 may further comprise a communication interface 1930 comprising hardware and/or software for realizing communication connectivity according to one or more communication protocols. The communication interface 1930 may provide the apparatus with radio communication capabilities, such as a transceiver, for communicating in the cellular communication system. The communication interface may, for example, provide a radio interface to terminal devices. The apparatus 1900 may further comprise another interface towards a core network such as the network coordinator apparatus and/or to the access nodes of the cellular communication system. The apparatus 1900 may further comprise a scheduler 1940 that is configured to allocate resources.

As used in this application, the term “circuitry” may refer to one or more or all of the following:
a. hardware-only circuit implementations (such as implementations in only analog and/or digital circuitry) and
b. combinations of hardware circuits and software, such as (as applicable):
   i. a combination of analog and/or digital hardware circuit(s) with software/firmware and
   ii. any portions of hardware processor(s) with software (including digital signal processor(s)), software, and memory(ies) that work together to cause an apparatus, such as a mobile phone, to perform various functions) and
c. hardware circuit(s) and or processor(s), such as a microprocessor(s) or a portion of a microprocessor(s), that requires software (for example firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

The techniques and methods described herein may be implemented by various means. For example, these techniques may be implemented in hardware (one or more devices), firmware (one or more devices), software (one or more modules), or combinations thereof. For a hardware implementation, the apparatus(es) of exemplary embodiments may be implemented within one or more application-specific integrated circuits (ASICs), digital signal processors (DSPs), digital signal processing devices (DSPDs), programmable logic devices (PLDs), field programmable gate arrays (FPGAs), graphics processing units (GPUs), processors, controllers, micro-controllers, microprocessors, other electronic units designed to perform the functions described herein, or a combination thereof. For firmware or software, the implementation can be carried out through modules of at least one chipset (for example procedures, functions, and so on) that perform the functions described herein. The software codes may be stored in a memory unit and executed by processors. The memory unit may be implemented within the processor or externally to the processor. In the latter case, it can be communicatively coupled to the processor via various means, as is known in the art. Additionally, the components of the systems described herein may be rearranged and/or complemented by additional components in order to facilitate the achievements of the various aspects, etc., described with regard thereto, and they are not limited to the precise configurations set forth in the given figures, as will be appreciated by one skilled in the art.

It will be obvious to a person skilled in the art that, as technology advances, the inventive concept may be implemented in various ways. The embodiments are not limited to the exemplary embodiments described above, but may vary within the scope of the claims. Therefore, all words and expressions should be interpreted broadly, and they are intended to illustrate, not to restrict, the exemplary embodiments.

1. A method comprising:
transmitting a first signal via at least a first switch, a first amplifier, a second switch and a power amplifier, wherein an output of the second switch is connected to a power amplifier path comprising at least the power amplifier, while transmitting the first signal;
receiving a feedback signal comprising a portion of the first signal, while transmitting the first signal, wherein the feedback signal is received by using a third switch to connect a receive path from an antenna to an input of a fourth switch, wherein an output of the fourth switch is connected to a down-conversion unit;
linearizing the first signal based at least partly on the received feedback signal;
switching between transmitting the first signal and receiving a second signal by switching an input of the first switch and the output of the second switch, wherein an output of the first switch and an input of the second switch are connected to an amplification path comprising at least the first amplifier; and
receiving the second signal via at least the third switch, the first switch, the first amplifier and the second switch, wherein the output of the second switch is disconnected from the power amplifier path while receiving the second signal, and wherein the third switch is used to connect the receive path from the antenna to the input of the first switch while receiving the second signal.

2. The method according to claim 1, further comprising bypassing at least the first switch, the first amplifier and the second switch via the third switch and the fourth switch, while receiving the second signal.

3. The method according to claim 1, further comprising bypassing the power amplifier via a fifth switch and a sixth switch, while transmitting the first signal.

4. The method according to claim 1, further comprising turning off the power amplifier, while receiving the second signal and/or while the power amplifier is bypassed.

5. The method according to claim 1, further comprising adjusting a supply voltage of the power amplifier and/or the first amplifier.

6. The method according to claim 1, wherein the first signal is transmitted via a phase-shifting component, and the second signal is received via the phase-shifting component.

7-8. (canceled)

9. The method according to claim 1, wherein the first signal is provided from a digital front-end unit via a first conversion unit, wherein the second signal is provided to the digital front-end unit via a second conversion unit, wherein the first conversion unit includes one or more of the following: a radio frequency digital-to-analog converter, a digital-to-analog converter, and/or a first heterodyning circuit, and
wherein the second conversion unit includes one or more of the following: a radio frequency analog-to-digital converter, an analog-to-digital converter, and/or a second heterodyning circuit.

10-11. (canceled)

12. A system comprising:
at least a first switch, a first amplifier, a second switch, and a power amplifier configured to transmit a first signal, wherein an output of the second switch is connected to a power amplifier path including at least the power amplifier, while transmitting the first signal, wherein the at least the first switch, the first amplifier, the second switch, and the power amplifier is further configured to
receive a feedback signal comprising a portion of the first signal, while transmitting the first signal, wherein the feedback signal is received by using a third switch to connect a receive path from an antenna to an input of a fourth switch, wherein an output of the fourth switch is connected to a down-conversion unit;
linearize the first signal based at least partly on the received feedback signal;
switch between transmitting the first signal and receiving a second signal by switching an input of the first switch and the output of the second switch, wherein an output of the first switch and an input of the second switch are connected to an amplification path comprising at least the first amplifier; and
receive the second signal via at least the third switch, the first switch, the first amplifier and the second switch, wherein the output of the second switch is disconnected from the power amplifier path while receiving the second signal, and wherein the third switch is used to connect the receive path from the antenna to the input of the first switch while receiving the second signal.

13. (canceled)

14. The system of claim 12, further comprising bypassing at least the first switch, the first amplifier and the second switch via the third switch and the fourth switch, while receiving the second signal.

15. The system of claim 14, further comprising bypassing the power amplifier via a fifth switch and a sixth switch, while transmitting the first signal.

16. The system of claim 15, further comprising turning off the power amplifier, while receiving the second signal and/or while the power amplifier is bypassed.

17. The system of claim 16, comprising adjusting a supply voltage of the power amplifier and/or the first amplifier.

18. The system of claim 17, wherein the first signal is further transmitted via a splitter, and the second signal is further received via the splitter, wherein the first signal is further transmitted via a circulator or a seventh switch, and the second signal is further received via the circulator or the seventh switch, wherein the first signal is further transmitted via a phase-shifting component, and the second signal is further received via the phase-shifting component, and wherein the first signal is provided from a digital front-end unit via a first conversion unit, and wherein the second signal is provided to the digital front-end unit via a second conversion unit.

19-21. (canceled)

22. The system of claim 12, wherein the first conversion unit comprises one or more of the following: a radio frequency digital-to-analog converter, a digital-to-analog converter, and/or a first heterodyning circuit; and wherein the second conversion unit comprises one or more of the following: a radio frequency analog-to-digital converter, an analog-to-digital converter, and/or a second heterodyning circuit.

23. A computer program comprising instructions for causing an apparatus to perform at least the following:
transmit a first signal via at least a first switch, a first amplifier, a second switch and a power amplifier, wherein an output of the second switch is connected to a power amplifier path comprising at least the power amplifier, while transmitting the first signal;
receive a feedback signal comprising a portion of the first signal, while transmitting the first signal, wherein the feedback signal is received by using a third switch to connect a receive path from an antenna to an input of a fourth switch, wherein an output of the fourth switch is connected to a down-conversion unit;
linearize the first signal based at least partly on the received feedback signal;
switch between transmitting the first signal and receiving a second signal by switching an input of the first switch and the output of the second switch, wherein an output of the first switch and an input of the second switch are connected to an amplification path comprising at least the first amplifier; and
receive the second signal via at least the third switch, the first switch, the first amplifier and the second switch, wherein the output of the second switch is disconnected from the power amplifier path while receiving the second signal, and wherein the third switch is used to connect the receive path from the antenna to the input of the first switch while receiving the second signal.
